(19) United States
(12) Patent Application Publication
(10) Pub. No.: US 2016/0020119 A1
(43) Pub. Date: Jan. 21, 2016

(54) Method of Controlling Recess Depth and Bottom ECD in Over-Etching

(71) Applicant: Macronix International Co., Ltd., Hsinchu (TW)

(72) Inventors: Sheng-Yuan Chang, Hsinchu (TW); An Chyi Wei, Hsinchu (TW)

(21) Appl. No.: 14/333,113

(22) Filed: Jul. 16, 2014

(51) Int. Cl. H01L 21/3213; H01L 27/105; H01L 23/532; H01L 21/311; H01L 23/528

(52) U.S. Cl. CPC H01L 21/32137; H01L 21/31116; H01L 23/528; H01L 23/53271; H01L 27/1052

(57) ABSTRACT

A semiconductor stack includes a carbon doped/implanted stop layer that reacts with etching plasma to form polymers that maintain bottom etched critical dimension (ECD) and avoid excess recess depth when over-etching in high-aspect-ratio structures.

### BACKGROUND OF THE INVENTION

1. Field of the Invention

The present invention relates generally to semiconductor fabrication methods and, more particularly, to etching techniques for forming high-aspect-ratio trench structures.

2. Description of Related Art

Fabrication of arrays of high-aspect-ratio semiconductor structures requires precise control of etching rates, profile shapes, and uniformity in aspect ratio. As semiconductor devices continue to be scaled down at an accelerating rate, the required degree of control becomes ever more difficult to achieve. As one example, when employing advanced/novel dry etch techniques, controlling an amount of recess at the bottom of high-aspect-ratio trenches can be particularly difficult.

Uncontrolled recess can be associated with unpredictable device performance leading to attendant poor quality control and higher manufacturing cost. The problem is getting more complicated when different recess dimensions are required in devices that are fabricated simultaneously owing to aspect ratios not being uniform over all regions of the device.

When a degree of over-etching is indicated or needed in the context of high-aspect-ratio structures, problems may be presented such as excess recess in some areas and/or unwanted reduction in etched critical dimension (ECD), e.g., in others. For instance, over-etching may undesirably reduce a bottom ECD in certain instances or regions. Generally, greater amounts of over-etching in a trench can create an excessively-deepened recess in an underlying oxide and/or, e.g., at the same time, undesirably reduce a bottom ECD.

A need thus exists in the prior art for a method of reducing the effect of over-etching on recess depth, whether the over-etching occurs inadvertently or by design. A further need exists for a method of preventing shrinkage of a bottom ECD when over etching occurs.

### SUMMARY OF THE INVENTION

The present invention addresses these and other needs with new methods of fabricating high-aspect ratio semiconductor structures. In one example, the present method comprises providing a structure including a semiconductor film stack having a first oxide layer, a stop layer that overlays the first oxide layer, one or more layers of conductive material different in composition from and disposed over or above the stop layer, and one or more dielectric layers. The method further comprises over-etching with a plasma to remove portions of the conductive and/or dielectric layers, creating or forming high-aspect-ratio structures. The over-etching may form polymers in and/or in close proximity to an upper surface of the stop layer, the polymers acting to inhibit etching of the stop layer. Penetration, for example, excessive depth of penetration of the etch into the stop layer thereby can be avoided, and/or shrinkage of a bottom etched critical dimension (ECD) can be reduced or prevented. In one implementation of the method, the forming of polymers is caused by plasma interacting with the stop layer.

In another implementation, the providing of the stop layer comprises providing a layer including one or more of polysilicon, oxide (such as an oxide of silicon), and silicon nitride doped and/or implanted with one or more of carbon and boron.

In yet another implementation, the providing of the structure comprises providing oxide layers, and the conductive material comprises polysilicon. Oxide and polysilicon (OP) may be disposed in alternate layers, and the high-aspect-ratio structures may comprise trenches.

While the structures and methods have or will be described for the sake of grammatical fluidity with functional explanations, it is to be expressly understood that the claims, unless indicated otherwise, are not to be construed as limited in any way by the construction of “means” or “steps” limitations, but are to be accorded the full scope of the meaning and equivalents of the definition provided by the claims under the judicial doctrine of equivalents.

Any feature or combination of features described or referenced herein are included within the scope of the present invention provided that the features included in any such combination are not mutually inconsistent as will be apparent from the context, this specification, and the knowledge of one skilled in the art. In addition, any feature or combination of features described or referenced may be specifically excluded from any embodiment or example of the present invention. For purposes of summarizing the present invention, certain aspects, advantages and novel features of the present invention are described or referenced. Of course, it is to be understood that not necessarily all such aspects, advantages or features will be embodied in any particular implementation of the present invention. Additional advantages and aspects of the present invention are apparent in the following detailed description and claims that follow.

### BRIEF DESCRIPTION OF THE DRAWINGS

FIG. 1 is a diagram of a prior-art semiconductor stack in which high-aspect-ratio trenches may be formed;

FIG. 2 is a cross-sectional diagram which shows a semiconductor device with known high-aspect-ratio trenches partially formed in the stack of FIG. 1 and which calls attention to an etched critical dimension (ECD) and an oxide recess depth;

FIG. 3 illustrates a result of conventionally lining and filling-in of the trenches of the structure of FIG. 2;

FIG. 4 is a diagram of a semiconductor stack including a stop layer suitable for forming high-aspect-ratio trenches according to the present invention;

FIG. 4A illustrates the semiconductor stack of FIG. 4 at an intermediate stage of a sequence of etching processes;

FIG. 5 shows an effect of the stop layer of FIG. 4 on a bottom ECD and an oxide recess depth when trenches are formed in the semiconductor stack of FIG. 4;

FIG. 6 portrays a result of filling-in of the trenches of the structure of FIG. 5; and

FIG. 7 is a flowchart outlining one implementation of a method of the present invention.

### DETAILED DESCRIPTION OF THE INVENTION

Embodiments and/or examples of the invention are now described and are illustrated in the accompanying drawings, instances of which are to be interpreted to be to scale in some implementations while in other implementations, for each instance, not. In certain aspects, use of like or the same reference designators in the drawings and description refers to the same, similar or analogous components and/or elements, while according to other implementations the same use should not. According to certain implementations, use of directional terms, such as, top, bottom, left, right, up, down, over, above, below, beneath, rear, and front, are to be construed literally, while in other implementations the same use should not. The present invention may be practiced in conjunction with various integrated circuit fabrication and other techniques that are conventionally used in the art, and only so much of the commonly practiced process steps are included herein as are necessary to provide an understanding of the present invention. The present invention has applicability in the field of semiconductor devices and processes in general. For illustrative purposes, however, the following description pertains to fabrication of high-aspect-ratio trenches and a related method of manufacture.

Referring more particularly to the drawings, FIG. 1 illustrates a prior-art semiconductor structure 250 formed on a substrate (not shown) to include a first oxide layer 255 and a collection of alternating layers of conducting material (e.g., polysilicon 260) and dielectric material (e.g., oxide 265). A second oxide layer 256 is formed over the OP layers 260/265, with notation that additional layers (not shown) may be overlaid on the structure to facilitate formation of trenches.

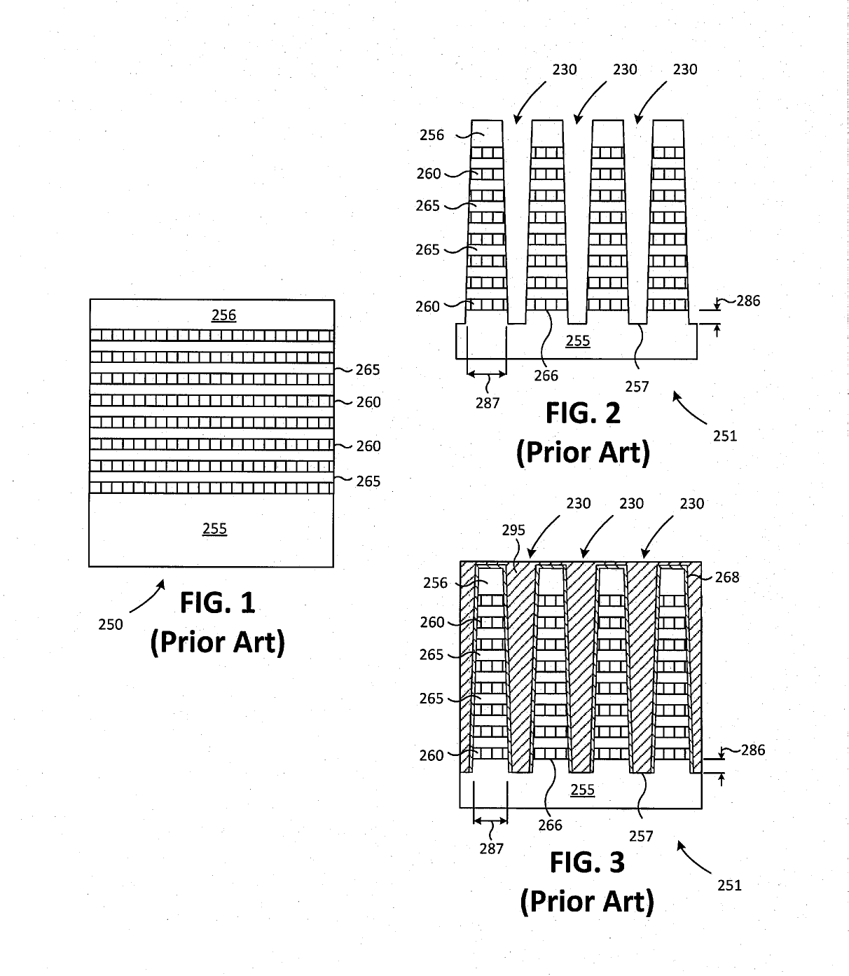

Such trenches, as shown at 230 in FIG. 2, may be used to form a bit line (BL) structure. The semiconductor stack 250 may be subjected to an etch of the OP layers 260/265 (i.e., an OP etch) using, for instance, a plasma of etchant(s), such as, e.g., NF₃/CH₂F₂/SF₆/N₂, to form trenches 230 having trench boundaries with cross-sections as shown in the structure 251 of FIG. 2. Each trench boundary in the example of FIG. 2 comprises OP layers 260/265 topped by the second oxide layer 256.

Known techniques for forming the high-aspect-ratio trenches 230 illustrated in FIG. 2 may require over-etching, e.g., to achieve a required trench depth. This over-etching may produce an undesirable increase in an oxide recess depth 286, whereby the etch or etching removes a portion of the oxide 255, which removal can result in unpredictable device properties or performance as described above. In the example of FIG. 2, the oxide recess depth is illustrated as a vertical distance between the bottom 266 of the lowest of the polysilicon layers 260 and the bottom 257 of the trench in the oxide layer 255. An additional undesirable side effect of over-etching according to the prior art can be a narrowing (i.e., shrinking) of an etched critical dimension (ECD). In the example in FIG. 2, this dimension is represented by a width of the lowest of the polysilicon layers 260, the ECD of which may be referred to as a bottom ECD 287.

Further steps in the conventional manufacturing process may comprise depositing a barrier, for example, an oxide-nitride-oxide (ONO) dielectric barrier 268 to line the trenches 230 and then filling-in with electrically conductive material such as polysilicon 295 according to that depicted in FIG. 3. A device made according to this method may have each of the trenches comprising a barrier material as a liner and a conductive fill-in, for example, comprising polysilicon.

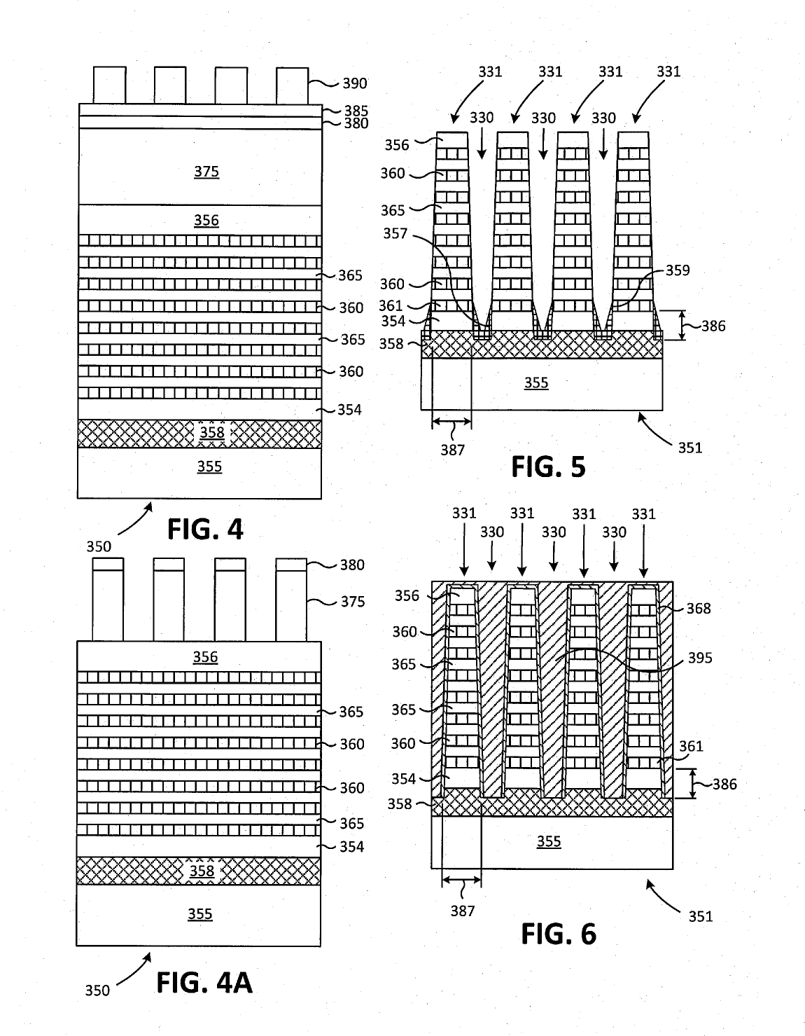

With reference to FIG. 4, the present invention may avoid problems of excess oxide depth (i.e., recess) and bottom ECD shrinkage by providing, according to an embodiment, one or more stop layers, such as stop layer 358. In FIG. 4, for simplicity, items referenced as 3xx may be the same as or correspond to the above-discussed 2xx elements.

According to the example in FIG. 4, a semiconductor structure 350 is formed on a substrate (not shown) to include a first oxide layer 355 having a thickness ranging from about 1.5 kÅ to about 3.5 kÅ, with a typical thickness being, for instance, about 2 kÅ. The stop layer 358 contacts, and is of a composition different from, a bottommost part of a collection of layers (cf., below), so that the stop layer 358 resides between the collection of layers and the first oxide layer 355.

The stop layer 358 may have a thickness ranging from about 0.5 kÅ to about 1.0 kÅ, with a typical thickness being about 0.5 kÅ, and may overlay the first oxide layer 355. The stop layer 358 may comprise materials such as polysilicon, oxide (e.g., an oxide of silicon), and silicon nitride (SIN). Such material(s) may be doped and/or implanted with elements such as carbon, boron and the like.

The semiconductor structure 350 is formed, further, to include a bottom oxide layer 354 that overlays the stop layer 358. A collection of layers of, e.g., multiple alternating layers each of, conducting material and insulating (e.g., dielectric) material may overlay the bottom oxide layer 354. The bottom oxide layer 354 may have a typical thickness of about 500 Å that may range from about 500 Å to about 1500 Å. The collection of layers, e.g., alternating layers, can comprise one or more of electrically conducting material, e.g., polysilicon 360, and dielectric material, e.g., oxide 365, which are different in composition from the stop layer 358, and which may be realized using respective techniques such as silane decomposition and plasma-enhanced chemical vapor deposition (PECVD) to overlay the first oxide layer 355. Each polysilicon layer 360 and oxide layer 365 can have a thickness ranging from about 200 Å to about 450 Å with typical values being, for instance, about 200 Å for the polysilicon layers 360 and about 250 Å for the oxide layers 365 in the example in FIG. 4. The number of alternating oxide/polysilicon (OP) layers 360/365 may range from about 8 to about 36 or more, with eight polysilicon layers 360 being shown in FIG. 4. A second oxide layer 356 having a thickness ranging from about 800 Å to about 2 kÅ, with a typical value being, for instance, about 1.6 kÅ, is formed, e.g., using a technique such as PECVD, over the OP layers 360/365.

Additional layers deposited in the example illustrated in FIG. 4 include an amorphous carbon (α-C) layer 375 having a thickness ranging from about 4 kÅ to about 7 kA with a typical value of about 4.5 kÅ. A dielectric antireflective coating (DARC®) layer 380 overlays the α-C layer 375, the DARC® layer 380 having a thickness which can be about 380 Å, or which may be as large as about 500 Å and as small as about 280 Å. The DARC® layer 380 may be overlaid with a bottom antireflective coating (BARC) layer 385 having, a thickness of which may be about 280 Å as a minimum and about 900 A as a maximum, with a typical thickness being about 320 Å. A photoresist (PR) pattern 390 is deposited on the BARC layer 385, in conjunction with an etch that will follow to form trenches.

In the example, the PR pattern 390 corresponds to a layout of trenches to be formed in the layers of the structure of FIG. 4. Such trenches may be incorporated or designed to form a bit line (BL) structure. In this regard, the semiconductor stack 350 may be subjected to an etch of the OP layers 360/365 (i.e., an OP etch) to accomplish the BL structure.

A flow for generating a pattern that may be usable for etching to form the trenches according to the contemplated BL structure may comprise transfer of the PR pattern into the BARC/DARC® layer 385/380, opening the BARC/DARC® using, for example, SF₆/CH₂F₂/He/N₂, followed sequentially by an α-C open step that may transfer the BARC/DARC® pattern into the α-C layer 375 by way of, for example, carbonyl sulfide (COS)/O₂/N₂ chemistry. A consequence of this flow may yield a pattern for trench etching as illustrated in FIG. 4A. Trench etching, following the flow and the pattern generated thereby, may comprise an OP etching process (i.e., an OP etch) employing, for example, a plasma of etchant(s), such as NF₃/CH₂F₂/SF₆/N₂, operable to transfer the α-C pattern to the OP layers 360/365. The transfer may thereby form high-aspect-ratio trenches 330 between a plurality of stacked strips 331 of alternating OP layers 360/365.

As shown in the cross-sectional schematic of FIG. 5, the trenches 330 may have trench boundaries with widths that may range from about 50 nm to about 200 nm, with a typical value being, for instance, about 86 nm. Widths of trenches 330 at an upper (e.g., top) region may range from about 59 nm to about 65 nm, with a typical width being, for instance, about 62 nm in the example in the figure. Widths of trenches 330 in a lower (e.g., bottom) region may have typical values of about 54 nm, or values ranging between about 51 nm to about 57 nm.

Formation of high-aspect-ratio trenches 330 as illustrated in FIG. 5 may require over-etching to achieve a required trench characteristic, e.g., shape, or dimension, e.g., depth. When the mentioned dimension is depth, it may range from about 5 kÅ to about 10.0 kÅ, with a typical value being about 5.2 kÅ.

According to an example of the invention, during the above-mentioned OP etch, the plasma of etchant(s) may interact with material in the stop layer 358 when the stop layer 358 is reached. This interaction may result in formation of extra or different polymer material 357, such as, for example, one or more carbon-like polymers, in and/or in proximity to the stop layer 358. That is, a distribution of polymer material 357 may extend to a sidewall 359 of a first (i.e., lowest) polysilicon layer 361 and may form in a bottom portion of the trenches 330 (i.e., an OP bottom area). Polymer material 357 located at the sidewall 359 may act to reduce ECD shrinkage due to over-etching. In addition, polymers located at the OP bottom area may inhibit further etching in the OP bottom area and/or may reduce a depth of penetration, i.e., depth of total recess 386 from, the first polysilicon layer 361 into the stop layer 358.

After completion of the OP etch (e.g., a dry etching process), excess polymer material may be removed using a dry/wet strip.

Subsequently, the trenches 330 in FIG. 5 may be lined with a barrier, for example, an ONO barrier 368, and may be filled-in with conducting material 395 such as, for example, polysilicon, as shown in FIG. 6.

Experiments performed to confirm certain advantages of the present invention have included performing OP etches of a type described above on a structure similar to that of FIG. 4A. Table 1 summarizes results of three of the OP etches as measured on images obtained with a scanning electron microscope (SEM).

TABLE 1

| Test Condition | EtchTime | Recess Depth (Å) | Bottom ECD (nm) |
|---|---|---|---|
| Prior Art | T1 | 768 | 31.8 |
| Present Invention | T2 | 628 | 33.7 |
| Present Invention | T3 | 847 | 31.7 |

Results of a control etch performed on a structure such as that shown in FIG. 1 representative of a prior-art process with no stop layer (cf. 358) are summarized in the first row of Table 1. The etch time, T1, in this example is a reference time of about 114 seconds. Under the stated conditions, the recess depth is observed to be 768 Å, with a measured bottom ECD of 31.8 nm.

A second OP etch, performed on a structure similar to that of FIG. 4A and having a stop layer (cf. 358) present, was otherwise essentially identical to the prior-art etch. The duration, T2, of the second OP etch was about the same as T1 and produced, as listed in Table 1, a recess depth of 628 Å, a decrease of about 18% relative to that observed with the prior-art process. The bottom ECD in this example was 33.7 nm, an increase of about 6% relative to that of the prior-art process. That is, shrinkage of the bottom ECD was entirely eliminated.

A third OP etch, representing an over-etch with the stop layer 358 present as in FIG. 4A, employed a duration, T3, of about 121 seconds, a value larger than both T1 and T2. The over-etch caused the recess depth to change to about 847 Å, an increase of about 10% over the prior-art value. However, the bottom ECD remained substantially unchanged relative to the prior-art value, even decreasing slightly to 31.7 nm in this example.

The information in Table 1 suggests or confirms that the present invention can lead to improved performance of etch processes used to fabricate semiconductor structures having high aspect ratios, even when over-etching is present. With reference to FIG. 5, the prior-art phenomena of shrinkage of bottom ECD 387 during over-etch is observed to be essentially eliminated, while an undesirable increase in recess depth 386 (as with the prior art) may be little, observably none, or insignificant. Reducing or eliminating shrinkage of the ECD of the bottom polysilicon layer 360 (i.e., bottom ECD 387) can be more difficult than reducing/eliminating ECD shrinkage of the other polysilicon layers 360 higher up in the trench 330. It is therefore expected that ECD shrinkage of the other polysilicon layers 360 in the trenches 330 likewise may be attenuated or eliminated.

Following the OP etching process, the trenches 330 in FIG. 5 may be lined with, for example, an ONO barrier 368 and filled-in with conducting material 395 such as, for example, polysilicon, as shown in FIG. 6.

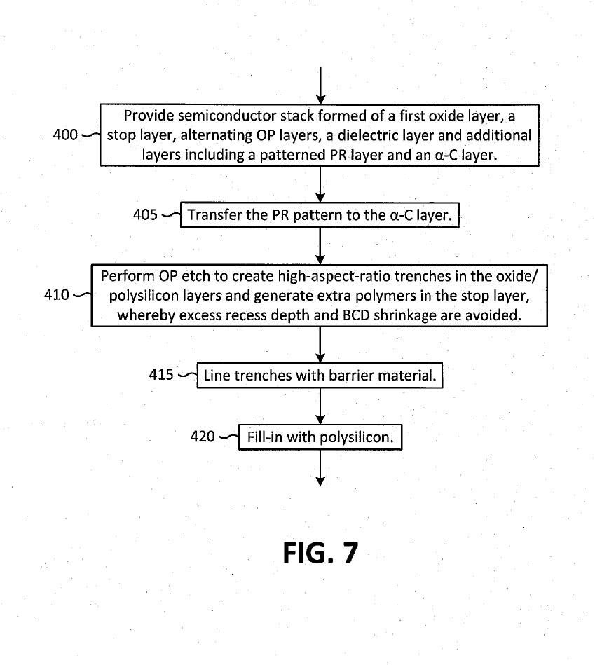

One implementation of a method of the present invention is summarized in the flowchart of FIG. 7. According to the illustrated implementation and with reference to FIG. 4, a semiconductor stack 350 is provided at step 400; the semiconductor stack 350, following the description above, may include a first oxide layer 355 overlaid with a stop layer 358. A bottom oxide layer 354 overlays the stop layer 358 in the illustrated example. The semiconductor stack 350 also is provided to include a plurality of alternating polysilicon layers 360 and oxide layers 365 overlaid by a dielectric layer (e.g., a second oxide layer 356) and additional layers as described above with reference to FIG. 4, the additional layers in the example including an α-C layer 375, a DARC layer 380, a BARC layer 385, and a patterned PR layer 390.

The layout of the patterned PR may be transferred at step 405 into the BARC/DARC® layers 385/380, and thence to the α-C layer 375. At step 410 an OP etch, which may employ such etchants as NF₃/CH₂F₂ and which may or may not include an over-etch introduced inadvertently or by design, forms trenches 330 having a high aspect ratio in the OP layers 360/365. Trenches 330 formed in the structure 351 separate a plurality of stacked strips 331 that include OP layers 360/365 and the second oxide layer 356. The stop layer 358 may, during the OP etch, react with the OP etchant(s) to form polymer material (i.e., extra polymers) 357 in addition to those created by the OP etch when the stop layer 358 is not present. This extra polymer material 357, which may comprise any of several materials such as, for example, carbon-like polymers having a large molecule that is made up of repeating subunits connected to each other by chemical bonds, may have an effect of preventing the OP etch and/or over-etch from proceeding deeply into the stop layer 358 so as to affect consistency or performance, thereby reducing a recess depth 386 (FIG. 5) and maintaining a bottom ECD 387 at a width that would be substantially the same as that observed without an over-etch.

According to one implementation of the method, dry/wet strips may be employed to remove excess polymers and by-products of the etch from the structure of FIG. 5 before deposition of a barrier material. FIG. 6 illustrates a result of deposition of a barrier layer, which may comprise a dielectric layer such as an ONO layer 368 to line the trenches 330 at step 415. Subsequently, a fill-in with conductive material such as metal and/or polysilicon 395 may be performed at step 420.

Although the disclosure herein refers to certain illustrated embodiments, it is to be understood that these embodiments have been presented by way of example rather than limitation. The strategy of combining a stop layer (cf. 358) with conventional semiconductor fabrication methods without requiring new tools or complicated changes in process flow can achieve simultaneous maintaining of ECD size and restraining of increases in recess depth even in the presence of high aspect ratios and over-etching. It will be clear to one skilled in the art that the invention may be applied to manufacture of such semiconductor products as flash memory, NAND and NOR devices, and 3D memory, thereby improving electrical performance of such devices. The intent accompanying this disclosure is to have such embodiments construed in conjunction with the knowledge of one skilled in the art to cover all modifications, variations, combinations, permutations, omissions, substitutions, alternatives, and equivalents of the embodiments, to the extent not mutually exclusive, as may fall within the spirit and scope of the invention as limited only by the appended claims.

1. A method, comprising:
providing a semiconductor film stack having a first oxide layer, a stop layer that overlays the first oxide layer, one or more layers of conductive material different in composition from and disposed above the stop layer, and one or more dielectric layers, wherein the stop layer comprises a doped material; and
over-etching with a plasma to remove portions of the conductive material layers and/or the dielectric layers, forming high-aspect-ratio structures.

2. The method as set forth in claim 1, wherein the plasma interacts with the stop layer in order to form polymers in proximity to an upper surface of the stop layer, the polymers acting to inhibit etching of the stop layer, thereby avoiding excessive depth of penetration of the etch into the stop layer and avoiding shrinkage of a bottom etched critical dimension (ECD).

3. The method as set forth in claim 1, wherein the providing of the stop layer comprises providing a stop layer comprising one or more of polysilicon, oxide, and silicon nitride doped with one or more of carbon and boron.

4. The method as set forth in claim 1, wherein:
the one or more layers of conductive material are separated by one or more layers of dielectric material; and
the providing comprises providing a stop layer comprising one or more of polysilicon, an oxide of silicon, and silicon nitride implanted with one or more of carbon and boron.

5. The method as set forth in claim 1, wherein:
the providing includes providing one or more oxide layers contacting the one or more layers of conductive material; and
the conductive material comprises polysilicon.

6. The method as set forth in claim 5, wherein:
the providing includes providing oxide and polysilicon (OP) layers; and
the over-etching removes portions of the OP layers to form the high-aspect-ratio structures.

7. The method as set forth in claim 6, wherein:
the OP layers provided comprise multiple layers of oxide and multiple layers of polysilicon;
the high-aspect-ratio structures formed are high-aspect-ratio trenches; and
the oxide and polysilicon layers are disposed as alternating layers of oxide and polysilicon.

8. The method as set forth in claim 1, wherein the over-etching comprises etching with a plasma comprising NF₃/CH₂F₂/SF₆/N₂.

9. A method of forming high-aspect-ratio trenches in a semiconductor film stack, the method comprising:
providing a plurality of layers of polysilicon and/or oxide on a dielectric layer above a substrate;
disposing a stop layer in contact with, and having a composition different from, a bottom part of the plurality of layers, so that the stop layer resides between the plurality of layers and the dielectric layer, wherein the stop layer comprises a doped material; and
performing a plasma etch to form a plurality of trenches in the plurality of layers, whereby the performing step is effective to maintain the size of a bottom etched critical dimension (ECD) of the plurality of trenches and produces substantially no recess in the stop layer or a negligible recess in the stop layer.

10. The method as set forth in claim 9, wherein the performing of a plasma etch produces a recess that extends downwardly beneath the bottom part of the plurality of layers a distance which is less than that distance would be if the plasma etch was performed without the presence of the stop layer.

11. The method as set forth in claim 10, wherein:
the performing of a plasma etch forms one or more polymers in the stop layer, and
the stop layer comprises one or more of polysilicon, oxide, and silicon nitride doped with one or more of carbon and boron.

12. A method of forming a semiconductor device having high-aspect-ratio trenches, comprising:
providing a stop layer comprising a doped material;
providing alternating oxide/polysilicon layers disposed above the stop layer;
over-etching with a plasma to form trenches above the stop layer, whereby the plasma reacts with the stop layer to form one or more polymers that limit an extent of the over-etching, thereby avoiding formation of a recess in the stop layer, and wherein the over-etching acts to maintain a size of a bottom etched critical dimension (ECD) of the trenches.

13. The method as set forth in claim 12, wherein the stop layer is formed of carbon-doped material.

14. The method as set forth in claim 13, wherein the carbon doped material comprises one or more of polysilicon, oxide, and silicon nitride.

15. (canceled)

16. The method as set forth in claim 12, wherein the over-etching comprises etching with a plasma comprising NF₃/CH₂F₂/N₂.

17.-20. (canceled)
